(19) United States
(12) Patent Application Publication
(10) Pub. No.: US 2007/0007663 A1
(43) Pub. Date: Jan. 11, 2007

(54) Semiconductor package having dual interconnection form and manufacturing method thereof

(76) Inventors: Seung-Duk Baek, Gyeonggi-do (KR); Sun-Won Kang, Seoul (KR)

Correspondence Address: MARGER JOHNSON & MCCOLLOM, P.C., 210 SW MORRISON STREET, SUITE 400, PORTLAND, OR, 97204, US

(21) Appl. No.: 11/371,291

(22) Filed: Mar. 7, 2006

(30) Foreign Application Priority Data
Jul. 6, 2005 (KR) 2005-60731

(51) Int. Cl. H01L 23/48

(52) U.S. Cl. 257/779

(57) ABSTRACT

An embodiment includes a dual interconnection form in which power/ground pads and signal pads of a semiconductor chip are electrically connected to a package substrate in different connection manners. First connection members that electrically connect the power/ground pads with the substrate have relatively large cross-sectional dimensions in comparison to its length, for example, solder bumps or gold bumps. Second connection members that electrically connect the signal pads with the substrate have relatively small cross-sectional dimensions in comparison its length, for example, conductive wires or beam leads. Such different ways of electrically connecting different kinds of pads with the substrate realize the most suitable electrical performance, effectively meeting the needs of high speed and low power consumption of the semiconductor devices.

### CROSS REFERENCE TO RELATED APPLICATIONS

This U.S. non-provisional application claims benefit of priority under 35 U.S.C.§119 from Korean Patent Application No. 2005-60731, filed on Jul. 6, 2005, the entire contents of which are incorporated herein by reference.

### BACKGROUND OF THE INVENTION

1. Field of the Invention

The present invention relates generally to semiconductor packaging technology, and more particularly, to a semiconductor package having dual interconnection form in which power/ground pads and signal pads of a semiconductor chip are electrically connected to a package substrate in different connection manners and a manufacturing method thereof.

2. Description of the Related Art

A great number of integrated circuit (IC) devices are fabricated in a silicon wafer and divided into individual IC chips. Each IC chip is then separated from the wafer, and assembled in a package which may be used in an electronic product. The functions provided by the package may include a structure to physically support the chip, a physical housing to protect the chip from the environment, an adequate means of removing heat generated by the chip, and electrical connections to allow signal and power access to and from the chip. Today, packaging technology is important in determining factors such as price, performance, and reliability of the final products.

A typical semiconductor package has used a lead frame as a package substrate that physically and electrically connects the chip with an external electronic system. However, as the number of input/output (I/O) pins increases and operating speeds become faster, such a lead frame type package may reach its operational limits. A ball grid array (BGA) package has been developed as an alternative to the lead frame package.

The BGA package uses a printed circuit board (PCB) instead of the lead frame. The PCB uses an array of solder balls as connection terminals for the package. The solder balls may be distributed over a chip surface, rather than just located peripherally at one or more chip edges as in the conventional lead frame package. Such a distribution of terminal locations may allow increases in I/O pin count and operating speed.

Lately, a specific structure of the BGA package has attracted attention in the art. In this structure, the PCB is directly disposed on the top surface of the chip where chip I/O pads are formed, rather than below the bottom surface of the chip as in normal BGA packages. This type of package is sometimes referred to as a board-on-chip (BOC) package and may reduce electrical paths between the chip and the PCB. In such packages, the electrical connection between the chip and the PCB is established by means of wire bonding or flip-chip bonding.

Wire bonding uses long, slender conductive wires with a relatively high inductance, which causes unfavorable problems such as simultaneous switching noise (SSN) of power/ground lines. Additionally, in most cases wire bonding requires the power/ground pads to be located at limited locations such as at the chip center or near the chip periphery, which results in a drop in the power delivery characteristic.

On the other hand, flip-chip bonding uses short, broad conductive bumps with relatively high capacitance, which lowers the signal transmission characteristic due to capacitive loading. Additionally, flip-chip bonding requires the conductive bumps and the solder balls to be located on different layers of the PCB, requiring the signal lines to use connection vias, thereby causing impedance discontinuity.

As newer semiconductor devices have ever faster operating speeds and lower power consumption, electrical aspects of the semiconductor package are becoming more important. However, wire bonding and flip-chip bonding have their respective problems as discussed above, and do not satisfy both the power/ground characteristic and the signal characteristic requirements.

### SUMMARY

Embodiments of the present invention provide a semiconductor package with improved electrical characteristics in both the power/ground aspect and the signal aspect and a manufacturing method thereof.

According to an embodiment of the present invention, a semiconductor package comprises a semiconductor chip that has power/ground pads and signal pads arranged on a top surface thereof, and a package substrate that is disposed above the semiconductor chip and has a top surface, a bottom surface, and conductive layers between the top and bottom surfaces. The semiconductor package of the invention further comprises first connection members that electrically connect the power/ground pads with the conductive layer at the bottom surface of the package substrate, and second connection members that electrically connect the signal pads with the conductive layer at the top surface of the package substrate. The semiconductor package further comprises external connection terminals formed on the conductive layer at the top surface of the package substrate. In the package, the first connection members have relatively large dimensions perpendicular to the electrical flow direction (hereinafter known as “cross-sectional dimensions”) in comparison with that in the electrical flow direction (hereinafter known as “length”). The first connection members may include solder bumps formed on the power/ground pads. In this case, the semiconductor package may further comprise an intermediate member interposed between the top surface of the semiconductor chip and the bottom surface of the package substrate, the intermediate member surrounding the solder bumps. The intermediate member may include underfill material, adhesive material, or non-conductive paste.

### BRIEF DESCRIPTION OF THE DRAWINGS

FIG. 1 is a cross-sectional view showing a semiconductor package in accordance with a first example embodiment of the present invention.

FIGS. 2A to 2C are partial perspective views showing manufacturing steps of the embodiment illustrated in FIG. 1.

FIG. 3 is a cross-sectional view partially showing a semiconductor package in accordance with a second example embodiment of the present invention.

FIG. 4 is a cross-sectional view partially showing a semiconductor package in accordance with a third example embodiment of the present invention.

FIG. 5 is a cross-sectional view partially showing a semiconductor package in accordance with a fourth example embodiment of the present invention.

FIG. 6 is a cross-sectional view partially showing a semiconductor package in accordance with a fifth example embodiment of the present invention.

### DETAILED DESCRIPTION

Embodiments of the present invention will now be described more fully hereinafter with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention, however, may be employed in varied and numerous embodiments without departing from the scope of the invention.

In this disclosure, well-known structures and processes are not described or illustrated in detail to avoid obscuring the present invention. Furthermore, the figures are not drawn to scale in the drawings. Rather, for simplicity and clarity of illustration, the dimensions of some of the elements are exaggerated relative to other elements.

### First Embodiment

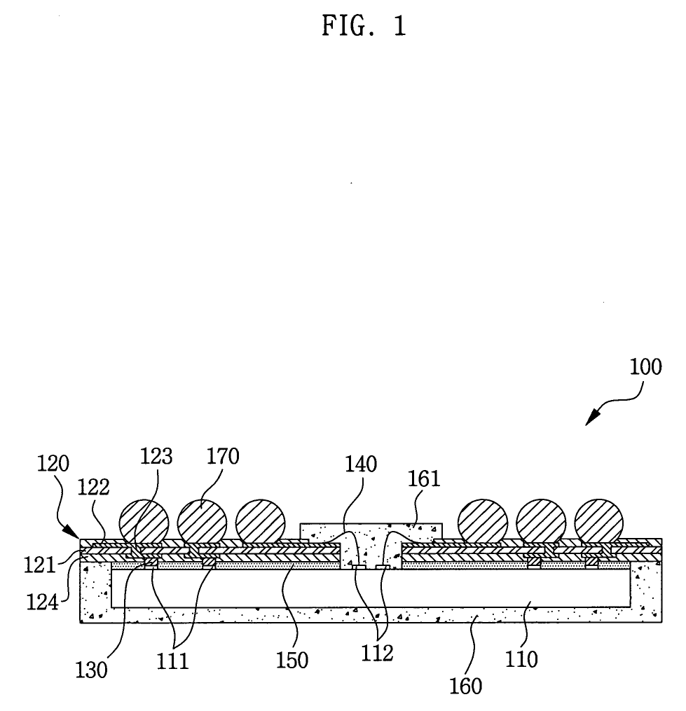

FIG. 1 shows, in a cross-sectional view, a semiconductor package 100 in accordance with a first example embodiment of the present invention.

Referring to FIG. 1, the semiconductor package 100 includes a semiconductor chip 110, a package substrate 120, first connection members 130, conductive wires 140 as second connection members, an intermediate member 150, encapsulating resins 160 and 161, and external connection terminals 170.

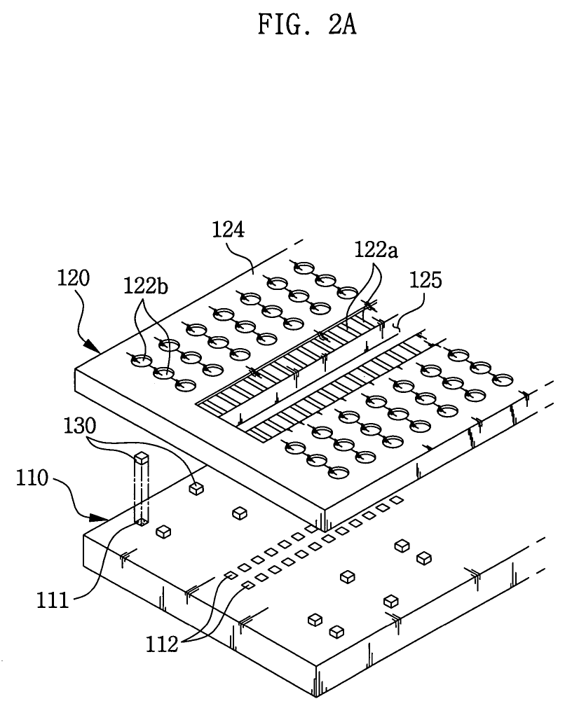

The semiconductor chip 110, for example a memory chip such as dynamic random access memory (DRAM), has a plurality of I/O pads 111 and 112 formed on a top surface thereof. The I/O pads are classified into power/ground pads 111 and signal pads 112. As depicted in FIG. 2A, which is a partial perspective view showing a manufacturing step of the semiconductor package 100, the signal pads 112 may be arranged in rows along a substantially central portion of the top surface of the semiconductor chip 110, and the power/ground pads 111 may be distributed over all of the top surface of the semiconductor chip 110.

The package substrate 120 is disposed above the semiconductor chip 110 and has a centrally elongated slot 125. The package substrate 120 may be a conventional PCB in which conductive layers 122 are formed on and under a dielectric layer 121 and connected to each other through vias 123 extending through the dielectric layer 121. Most portions of the conductive layers 122 may be covered with upper and lower protective layers 124, and the remainder may be exposed for electrical connections.

The electrical connection between the semiconductor chip 110 and the package substrate 120 may be established in dual interconnection form in the semiconductor package 100 according to some embodiments of the present invention. Specifically, the power/ground pads 111 and the signal pads 112 of the semiconductor chip 110 are electrically coupled to the package substrate 120 in different connection manners. The first connection member 130 connects the power/ground pads 111 with the package substrate 120, and the conductive wires 140 connect the signal pads 112 with the package substrate 120.

As mentioned above, the first connection members 130 have relatively large dimensions perpendicular to the electrical flow direction (hereinafter known as “cross-sectional dimensions”) in comparison with that in the electrical flow direction (hereinafter known as “length”). In other words, the cross-sectional dimensions, such as a cross-sectional width or diameter, of the first connection member 130 is relatively large compared to its length.

Thus, the shape of the first connection member 130 may resemble a one-or-more sided disk-shaped object. In contrast, the second connection members 140 have relatively small dimensions perpendicular to the electrical flow direction (cross-sectional dimension) in comparison with that in the electrical flow direction (length). In other words, the cross-sectional width or diameter of the second connection member 140 is relatively small compared to its length. Thus, the shape of the second connection member may resemble an elongated wire.

In comparing the two connections members, assuming each has the same length, the first connection member would have a larger volume than the second connection member (i.e., the cross-sectional width of the first connection member would be larger than the cross-sectional width of the second connection member). In another method of comparison, the ratio of the cross-sectional width to length of the first connection member 130 is relatively larger than the same ratio would be for the second connection member 140.

The first connection member 130 electrically connects the power/ground pad 111 with the lower conductive layer 122 at the bottom surface of the package substrate 120. In this embodiment, the first connection member 130 is a conductive bump such as a solder bump, which may be initially formed on the power/ground pad 111 and then joined with the conductive layer 122. As discussed above, the first connection member 130 including the solder bump may be characterized by having relatively large cross-sectional dimensions in comparison with its length. The first connection members 130 therefore have low inductance, and thereby reduce SSN of the power/ground lines. Furthermore, since the first connection member 130 does not limit the location of the power/ground pads 111, the power/ground pads 111 may be distributed over substantially all of the top surface of the semiconductor chip 110. As a result, improvements in the power delivery characteristic are possible.

The conductive wire 140 electrically connects the signal pad 112 with the upper conductive layer 122 at the top surface of the package substrate 120. In this embodiment, the second connection members may be conductive wires 140, which are bonded to the signal pad 112 at one end and to the conductive layer 122 at the other end. The second connection member including the conductive wire 140 is characterized by having relatively small cross-sectional dimensions in comparison with its length. The second connection members therefore have low capacitance and reduced capacitive loading, thereby improving the signal transmission characteristic. Furthermore, since both the conductive wire 140 and the external terminals 170 are connected to the upper conductive layer 122, no via is needed on the signal lines.

The intermediate member 150 may be interposed between the top surface of the semiconductor chip 110 and the bottom surface of the package substrate 120, offering mechanical adhesive strength. Also, the intermediate member 150 surrounds the solder bumps 130 to fix and protect the solder bumps 130. The intermediate member 150 may be an underfill material, adhesive material, or non-conductive paste, all of which are typically used in the art.

The encapsulating resins 160 and 161 not only encompass the bottom and lateral sides of the semiconductor chip 110, but also enclose the conductive wires 140. The encapsulating resin 160 around the semiconductor chip 110 may expose the bottom surface of the semiconductor chip 110 to add a heat-dissipating plate onto the bottom surface of the semiconductor chip 110.

The external connection terminals 170 are formed on the upper conductive layer 122 exposed through the top surface of the package substrate 120. The external connection terminals 170 may be solder balls.

FIGS. 2A to 2C show, in partial perspective views, manufacturing steps of the embodiment illustrated in FIG. 1. As shown in FIG. 2A, at the outset, a semiconductor chip 110 and a package substrate 120 are provided. Solder bumps 130 are already formed on power/ground pads 111 of the semiconductor chip 110. As described above, signal pads 112 are centrally arranged in rows on the top surface of the semiconductor chip 110, and the power/ground pads 111 are distributed over substantially all of the top surface of the semiconductor chip 110.

The package substrate 120 may have a centrally elongated slot 125. When the semiconductor chip 110 is attached to the package substrate 120, the slot 125 exposes the signal pads 112 on the semiconductor chip 110. The top and bottom surfaces of the package substrate 120 are covered with the protective layers 124. However, portions of the conductive layer 122 on the top surface of the package substrate 120 are exposed through the protective layers 124, defining wire pads 122a along both edges of the slot 125, and further, defining ball pads 122b throughout the top surface. Although not depicted in the drawing, the bottom surface of the package substrate 120 also has exposed portions of the conductive layer 122, namely, bump pads.

Subsequently, as shown in FIG. 2B, the semiconductor chip 110 is attached to the package substrate 120. At this time, the solder bumps 130 formed on the power/ground pads 111 of the semiconductor chip 110 are joined with the bump pads exposed from the bottom surface of the package substrate 120. An intermediate member 150 may be interposed between the semiconductor chip 110 and the package substrate 120. When the intermediate member is an underfill material, it may be formed after the attachment process of the semiconductor chip and package substrate. When the intermediate member is an adhesive material or non-conductive paste, it may be formed before the attachment process of the semiconductor chip and package substrate.

After the attachment process of the semiconductor chip and package substrate, a wire-bonding process is performed. Specifically, one end of a conductive wire 140 is bonded to the signal pad 112 exposed within the slot 125. Further, the other end of the conductive wire 140 is bonded to the wire pad 122a exposed on the package substrate 120 in the vicinity of the slot 125.

Subsequently, as shown in FIG. 2C, encapsulating resins 160 and 161 are formed to encompass exposed sides of the semiconductor chip 110 and to enclose the conductive wires 140. The encapsulating resins 160 and 161 may be formed at the same time by using a molding technique or formed separately by using a dispensing technique.

Finally, solder balls, as external connection terminals 170, are formed on the ball pads 122b exposed on the package substrate 120.

### Second Embodiment

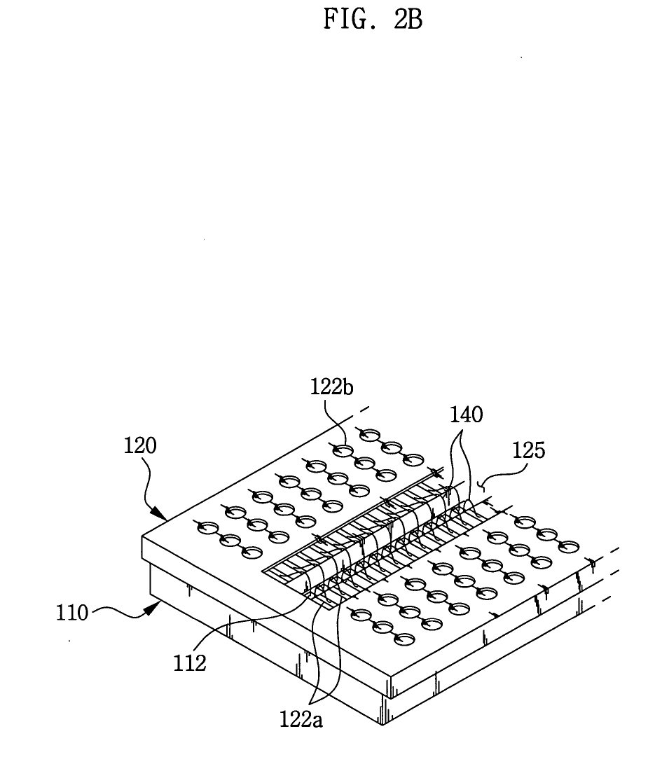

FIG. 3 partially shows, in a cross-sectional view, a semiconductor package in accordance with a second embodiment of the present invention. Among elements in the second embodiment, those that are the same as elements in the previous embodiment will use the same reference numerals, and descriptions thereof will be omitted.

Referring to FIG. 3, the semiconductor package 200 in this embodiment is characterized by using gold bumps 230 as the first connection members instead of using the solder bumps in the previous embodiment.

The gold bumps 230 are formed on the power/ground pads 111. In the case of copper being used for the conductive layer 122 of the package substrate 120, the gold bumps 230 may have poor adhesion with the conductive layer 122. It is therefore desirable to insert an anisotropic conductive member 250 between the gold bumps 230 and the conductive layer 122. The anisotropic conductive member 250 has a plurality of conductive particles 252 distributed in an insulating resin layer 251, and is interposed in the form of film or paste between the semiconductor chip 110 and the package substrate 120. The anisotropic conductive member 250 may therefore play the same role as the intermediate member (150 in FIG. 1) discussed in the first embodiment.

### Third Embodiment

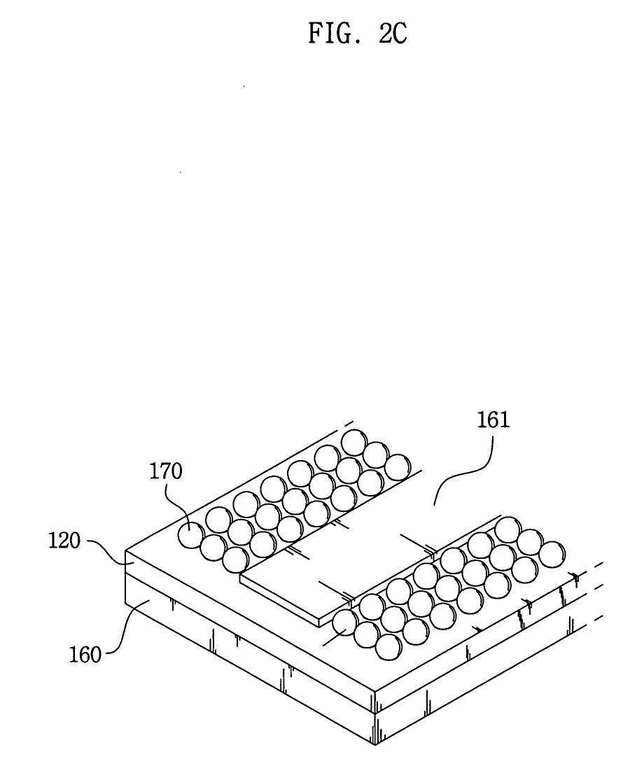

FIG. 4 partially shows, in a cross-sectional view, a semiconductor package in accordance with a third example embodiment of the present invention. Among elements in the third embodiment, those that are the same as elements in the previous embodiments will use the same reference numerals, and descriptions thereof will be omitted.

Referring to FIG. 4, the semiconductor package 300 in this embodiment is characterized by using gold stud bumps 330 as the first connection members instead of using the solder bumps or the gold bumps in the previous embodiments.

The gold stud bump 330 may be obtained by forming the wire balls onto the power/ground pad 111 of the semiconductor chip 110. Additionally, the conductive layer 122 of the package substrate 120 may be preferably covered with solder material 331 for adhesion with the gold stud bump 330. As in the first embodiment, the package 300 according to this embodiment may further include the intermediate member 150 such as underfill material, adhesive material, or non-conductive paste.

### Fourth Embodiment

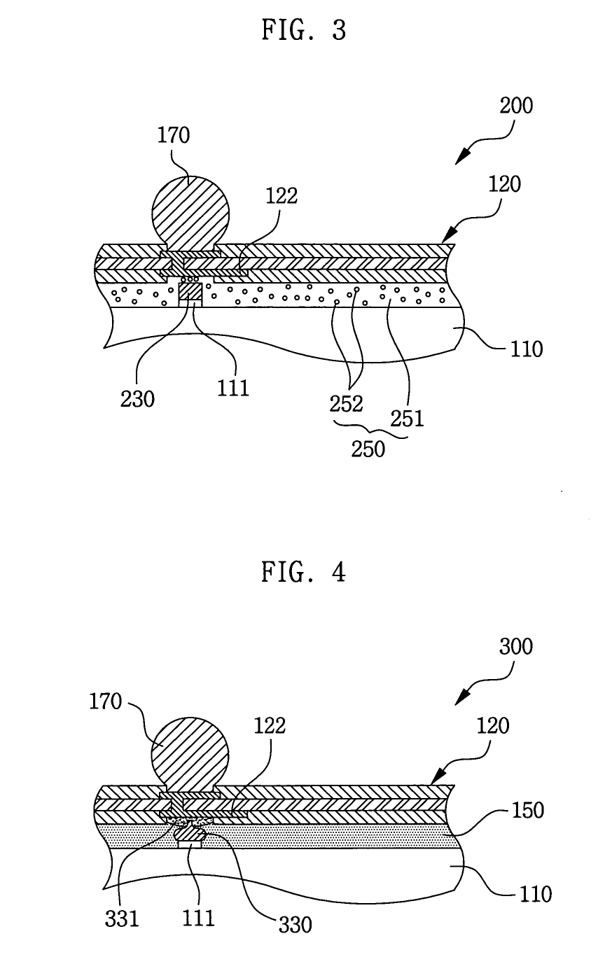

FIG. 5 partially shows, in a cross-sectional view, a semiconductor package in accordance with a fourth example embodiment of the present invention. Among elements in the fourth embodiment, those that are the same as elements in the previous embodiments will use the same reference numerals, and descriptions thereof will be omitted.

Referring to FIG. 5, the semiconductor package 400 in this embodiment is characterized by using beam leads 440 as the second connection members instead of using the conductive wires (140) in the first embodiment.

A package substrate 420 includes a film-type dielectric layer 421, an upper conductive layer 422 on the dielectric layer 421, and a protective layer 424 covering the conductive layer 422. The beam leads 440 extend from the conductive layer 422 and are bonded to the signal pads 112 of the semiconductor chip 110.

### Fifth Embodiment

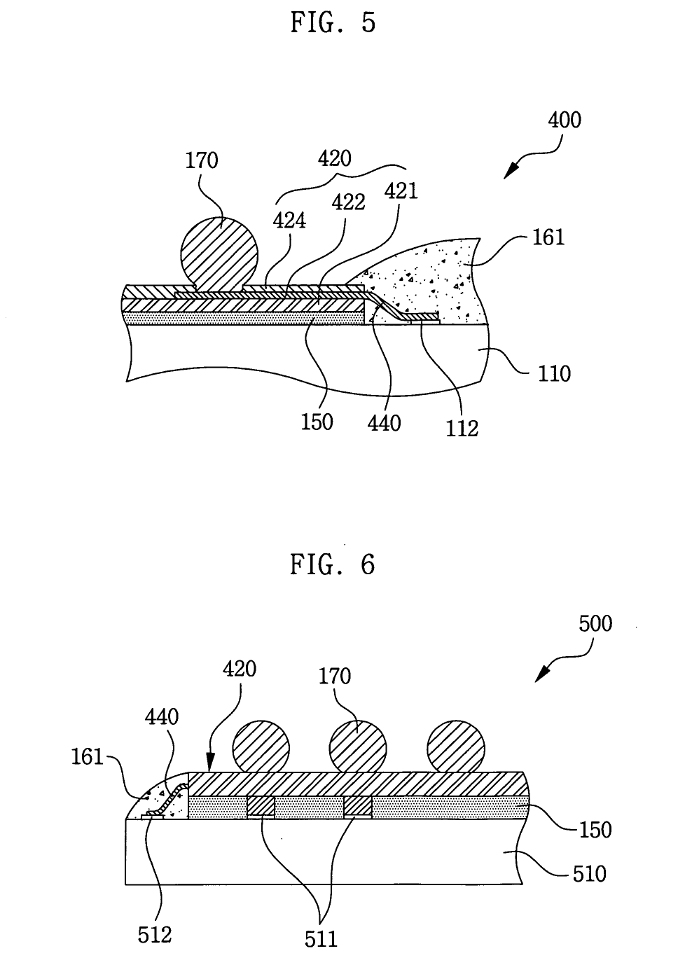

FIG. 6 partially shows, in a cross-sectional view, a semiconductor package in accordance with a fifth example embodiment of the present invention. Among elements in the fifth embodiment, those that are the same as elements in the previous embodiments will use the same reference numerals, and descriptions thereof will be omitted.

Referring to FIG. 6, the semiconductor package 500 in this embodiment is characterized by signal pads 512 arranged along a peripheral portion of a chip 510, rather than along a central portion as in the first embodiment. Power/ground pads 511 are distributed over the chip surface as in the first embodiment.

As discussed above in several embodiments, different ways of electrically connecting the power/ground pad and the signal pad with the substrate may realize the most suitable electrical performance. The semiconductor package according to the invention may therefore effectively meet the needs of high speed and low power consumption of the semiconductor devices.

While this invention has been particularly shown and described with reference to example embodiments thereof, it will be understood by those skilled in the art that various changes in form and details may be made therein without departing from the spirit and scope of the invention as defined by the appended claims.

What is claimed is:

1. A semiconductor package comprising:
a semiconductor chip having power/ground pads and signal pads arranged on a top surface thereof;
a package substrate disposed above the semiconductor chip and having a top surface, a bottom surface, the package substrate including one or more conductive layers;
first connection members electrically connecting the power/ground pads with the conductive layer at the bottom surface of the package substrate;
second connection members electrically connecting the signal pads with the conductive layer at the top surface of the package substrate; and
external connection terminals formed on the conductive layer at the top surface of the package substrate,
wherein a ratio of a cross-sectional width to a length of the first connection members is relatively larger than the ratio of a cross-sectional width to a length of the second connection members.

2. The package of claim 1, wherein the first connection members include solder bumps formed on the power/ground pads and joined with the conductive layer.

3. The package of claim 2, further comprising an intermediate member interposed between the top surface of the semiconductor chip and the bottom surface of the package substrate, surrounding the solder bumps.

4. The package of claim 3, wherein the intermediate member includes at least one of an underfill material, adhesive material, and non-conductive paste.

5. The package of claim 1, wherein the first connection members include gold bumps formed on the power/ground pads, and an anisotropic conductive member interposed between the gold bumps and the conductive layer.

6. The package of claim 5, wherein the anisotropic conductive member includes at least one of anisotropic conductive film and anisotropic conductive paste.

7. The package of claim 1, wherein the first connection members include gold stud bumps formed on the power/ground pads, and a solder material formed on the conductive layer.

8. The package of claim 7, further comprising an intermediate member interposed between the top surface of the semiconductor chip and the bottom surface of the package substrate, surrounding the gold stud bumps and the solder material.

9. The package of claim 8, wherein the intermediate member includes at least one of underfill material, adhesive material, and non-conductive paste.

10. The package of claim 1, wherein the second connection members include conductive wires, each of which is connected to the signal pad at one end and to the conductive layer at the other end.

11. The package of claim 1, wherein the second connection members include beam leads extending from the conductive layer and connected to the signal pads.

12. The package of claim 1, wherein the signal pads are arranged along a central portion of the top surface of the semiconductor chip, and the power/ground pads are distributed over substantially all of the top surface of the semiconductor chip.

13. The package of claim 1, wherein the signal pads are arranged along a peripheral portion of the top surface of the semiconductor chip, and the power/ground pads are distributed over substantially all of the top surface of the semiconductor chip.

14. The package of claim 1, wherein the first and second connection members have the same length.

15. A method of manufacturing a semiconductor package, the method comprising:
providing a semiconductor chip having power/ground pads and signal pads arranged on a top surface thereof;
providing a package substrate having a conductive layer extending between top and bottom surfaces thereof;
electrically coupling the first connection members with the conductive layer at the bottom surface of the package substrate by attaching the semiconductor chip to the package substrate;
electrically coupling second connection members with the signal pads of the semiconductor chip and the conductive layer at the top surface of the package substrate, wherein a ratio of a cross-sectional width to a length of the first connection members is relatively larger than a ratio of a cross-sectional width to a length of the second connection members; and
forming external connection terminals on the conductive layer at the top surface of the package substrate.

16. The method of claim 15, further comprising:
electrically connecting the first connection members, providing an intermediate member between the top surface of the semiconductor chip and the bottom surface of the package substrate so as to surround the first connection members before attaching the semiconductor chip to the package substrate.

17. The method of claim 15, further comprising:
electrically connecting the first connection members, providing an intermediate member between the top surface of the semiconductor chip and the bottom surface of the package substrate so as to surround the first connection members after attaching the semiconductor chip to the package substrate.

18. The method of claim 15, wherein the first and second connection members have the same length.

19. A method of manufacturing a semiconductor package comprising:
forming a package substrate having a conductive layer over a semiconductor chip having power/ground pads and signal pads arranged on a top surface of the semiconductor chip;
electrically connecting the conductive layer at a bottom surface of the semiconductor package to the power/ground pads with first connection members; and
electrically connecting the conductive layer at a top surface of the semiconductor package to the signal pads with second connection members, wherein a ratio of a cross-sectional width to a length of the first connection members is relatively larger than a ratio of a cross-sectional width to a length of the second connection members.

20. The method of claim 19, further comprising forming an intermediate member between the semiconductor chip and the substrate package to surround the first connection members.
